(19) United States
(12) Patent Application Publication
(10) Pub. No.: US 2022/0321049 A1
(43) Pub. Date: Oct. 6, 2022

(54) METHOD FOR DETECTING A BLOCKAGE OF AN ELECTRIC MOTOR

(71) Applicant: ebm-papst Mulfingen GmbH & Co. KG, Mulfingen (DE)

(72) Inventors: Fabian SCHNEIDER, Rot am See (DE); Maxim KRONEWALD, Bad Mergentheim (DE)

(21) Appl. No.: 17/693,322

(22) Filed: Mar. 12, 2022

(30) Foreign Application Priority Data
Mar. 31, 2021 (DE) 10 2021 108 229.3

(51) Int. Cl. H02P 29/024; H02P 6/182

(52) U.S. Cl. CPC H02P 29/024; H02P 6/182; H02P 29/032

(57) ABSTRACT

A method for detecting a blockage condition of an electric motor, preferably a BLDC motor, that is operated by commutation electronics, wherein the blockage condition is determined by evaluating the EMF in comparison to a stored threshold value S_{BASE} comprising:
a) determining the EMF by taking into account a temperature-dependent parameter representing the stator resistance R of the motor;
b) determining a deviation of the determined EMF due to the influence of the actual winding temperature;
c) determining a correction factor k for correcting the parameter for the stator resistance in order to determine a corrected EMF and
d) determining whether the motor is blocked by comparing the temperature-corrected EMF to the stored threshold value.

### CROSS-REFERENCE TO RELATED APPLICATION

This application claims the benefit and priority of German Application No. 10 2021 108 229.3, filed on Mar. 31, 2021. The entire disclosure of the above application is incorporated herein by reference.

### FIELD

The disclosure relates to a method for detecting a motor blockage of an electric motor, in particular a BLDC motor, and accordingly to a method for protecting such an electric motor from overload.

### BACKGROUND

A brushless DC motor (Brushless DC Motor, abbreviated BLDC or BL motor also called electronically commutated motor, EC motor for short) is not based on the functional principle of a DC machine, contrary to the name. It is constructed like a three-phase synchronous machine with excitation by permanent magnets. The three-phase winding is controlled by a suitable circuit that generates a moving magnetic field that pulls the permanently excited rotor. The control behavior is largely similar to a DC shunt machine.

If an electric motor, in particular a BLDC motor, is supplied with its nominal motor current when it is blocked, the windings will heat up. This will destroy the motor. In regular, normal operation, the motor is cooled by its rotary movement. For this reason, the permissible motor currents in normal operation can be higher than when the motor is blocked. There are different concepts in the prior art for preventing such states or for detecting them in time.

For this purpose, an evaluation of Hall signals or encoder signals is proposed in the prior art, a direct evaluation based on the speed.

DE 101 21 766 A1, for example, discloses a drive assembly for a fan in motor vehicles. It has an electric fan motor operated on a DC voltage mains and a device for controlling the speed of the fan motor by changing the operating voltage applied to the fan motor. However, a blockage and/or sluggishness of the fan motor cannot always be detected. Thus, the fan motor and its supply lines unacceptably overheat. This may lead to the fan motor being destroyed if the loads are sustained.

DE 103 36 953 A1 discloses a device with a mechanism for detecting a motor current of the fan motor. The mechanism can include a current measuring resistor, for example. Furthermore, the device contains a drive circuit that has a storage means. A permitted maximum current of the fan motor can be stored in this storage means, for example by a service technician in a specialist workshop, by the manufacturer of the fan motor or the like. The control circuit then compares the detected motor current with the stored maximum current, so that the control circuit detects the blockage and/or sluggishness of the fan motor as soon as the detected motor current exceeds the stored maximum current. Since the maximum current is fixed, the full power range of the motor cannot be used. In order to increase this value depending on the speed, the mechanical speed of the motor must be detected.

The electromotive force (EMF) and—equivalently—the internal voltage, are historical designations indicating the source voltage of an electrical voltage source. The voltage induced in the windings of an electric motor or generator by rotation is also called EMF.

Accordingly, the rotor of an electric motor rotating in the magnetic field of a stator or the magnetic rotor of a generator induce a voltage in the respective windings. In the case of motors, this induced voltage is called back EMF. It is irrelevant which voltage is actually applied to the motor or the generator—the difference between the two voltages drops at the ohmic resistance of the windings or is caused by leakage currents.

In addition to the solutions described, there are also methods where the calculated back EMF is compared with a fixed threshold in order to obtain information about a motor blockage condition. In such sensor-less rotor position estimators, that determine the position using an induced voltage (EMF), the parameters required to calculate the EMF are usually measured under laboratory conditions [temperature of about 20° C.] and stored in the software as constant, i.e. fixed, parameters.

According to a physical model of the machine (PMSM), the EMF is calculated from the output motor voltage via the parameters (stator resistance, inductance in the Q axis, inductance in the D axis). In addition to the actual position determination of the rotor, the EMF can also be used to detect a blocked motor, since the magnitude of the EMF is proportional to the speed. For this purpose, it is known to store a fixed and thus defined threshold in the software in order to evaluate whether the motor is rotating or blocked. The threshold should be as small as possible, since this variable defines the minimum speed of the drive. If after a certain time the determined EMF is less than the defined minimum threshold while the motor is actively commutated via the output stage, then it can or may be assumed that the motor is blocked.

However, the following problems occur in practice, so that the known method is still unsatisfactory.

Copper, for example, has a resistance temperature coefficient of 3.9·10⁻³ [K⁻¹]. The temperature in the motor winding, which is of wound copper wire, typically can have values of −40° C. to +180° C.

When determining the EMF of the q component and of the d component of the voltage values for U_{d} and U_{q}, the resistance parameter R is considered in addition to the q component and the d component of the current i_{q} and i_{d}.

The EMF is determined as follows:

$${u}_{d} = R \cdot {i}_{d} - {ω}_{el} \cdot {L}_{q} \cdot {i}_{q} + {L}_{d} \cdot \frac{a}{dt} {i}_{d} \\ {u}_{q} = R \cdot {i}_{q} + {ω}_{el} \cdot {L}_{d} \cdot {i}_{d} + {L}_{q} \cdot \frac{d}{dt} {i}_{q} + {ω}_{el} \cdot {Ψ}_{PM}$$

The values u_{d}, u_{q} correspond to the terminal voltage and the following term corresponds to the u_EMF:

ωₑₗ·Ψ_{PM}

This results in a deviation of [−23.4%/+62%] for the parameter (R) measured at ambient temperature. As a result of this scattering, a blockage detection based on an EMF calculation may not occur when the winding is “hot” or a blockage may be detected when the winding is “cold” even though the motor is rotating freely. There is therefore a need to further develop the solution known in the prior art.

### SUMMARY

The object of the disclosure is to detect a blockage of a motor in a safe and reliable way by means of an EMF calculation.

This object is achieved by the combination of features according to a method for detecting a blockage condition of an electric motor, preferably a BLDC motor, that is operated by commutation electronics. The blockage condition is determined by evaluating the EMF in comparison to a stored threshold value S_{BASE} comprising:

a) determining the EMF by taking into account a temperature-dependent parameter representing the stator resistance R of the motor;

b) determining a deviation of the determined EMF due to the influence of the actual winding temperature;

c) determining a correction factor k for correcting the parameter for the stator resistance in order to determine a corrected EMF, and

d) determining whether the motor is blocked by comparing the temperature-corrected EMF to the stored threshold value.

A method for detecting a blockage condition of an electric motor, preferably a BLDC motor, that is operated by a commutation electronics, wherein the blockage condition is determined by evaluating the EMF compared to a stored threshold value S_{BASE}, is as follows:

a) determining the EMF by taking into account a temperature-dependent parameter representing the stator resistance R of the motor;

b) determining a deviation of the determined EMF due to the influence of the actual winding temperature;

c) determining a correction factor k for correcting the parameter for the stator resistance in order to determine a corrected EMF and

d) determining whether the motor is blocked by comparing the temperature-corrected EMF to the stored threshold value.

Preferably, the foregoing equation is used as a basis for determining the EMF. If the determined (not corrected) EMF falls below the threshold value S_{BASE}, because the motor temperature is too high, a blockage condition would be incorrectly detected. However, based on steps b) and c) according to the disclosure, a temperature-dependent correction factor for the stator resistance is determined. Thus, a corrected EMF is obtained, that is higher than the threshold value S_{BASE}. Thus, the absence of a motor blockage is recognized.

In a preferred embodiment of the disclosure, a sensor detects the temperature of the motor windings to determine the correction factor k. Preferably a temperature sensor is used. The parameter for the stator resistance R for determining the EMF is adjusted accordingly. This measurement therefore represents a direct temperature measurement that can be introduced directly in the evaluation.

In an alternative embodiment of the disclosure, the temperature to determine a correction factor k is determined indirectly via a temperature measurement at another motor reference position or at a motor module instead of measuring the temperature of the motor windings using a sensor. For example, a stored characteristic temperature map can be used in order to use reference points where the temperature is detected in order to obtain the winding temperature in the motor and thus carry out the correction.

In another advantageous solution, the threshold value S_{ADAPTIVE} for blockage detection is adaptively adapted to the motor current I, in particular, via a current-dependent function for the threshold value according to the following formula:

S_{ADAPTIVE}=S_{BASE}+R·I·k,

where S_{BASE} is the stored threshold, R is the stator resistance, I is the motor current and k is a specific correction factor.

In other words, this solution represents another way of correcting the error in the motor model by taking into account that an error only occurs if a current is also flowing (Rs(T)·I). In the software used, the threshold (threshold value S_{BASE} for blockage detection) is adaptively adjusted for this purpose. A further factor is used to weigh the correction term (the extent of the error to be expected).

The correction factor can be stored in the system or in a memory in different ways. For example, fixed values or switchable values can be stored for the correction factor k or the correction factor k can be determined using a term or a corresponding characteristic map.

Other advantageous developments of the disclosure are illustrated in the dependent claims or are presented in more detail in the following together with the description of the preferred embodiment of the disclosure with reference to the FIGURES.

Further areas of applicability will become apparent from the description provided herein. The description and specific examples in this summary are intended for purposes of illustration only and are not intended to limit the scope of the present disclosure.

### DRAWINGS

Other advantageous refinements of the disclosure are characterized in the subclaims and/or depicted in greater detail below together with the description of the preferred embodiment of the disclosure with reference to the figures. In the drawing:

FIG. 1 is an exemplary view for determining the factor k.

### DETAILED DESCRIPTION

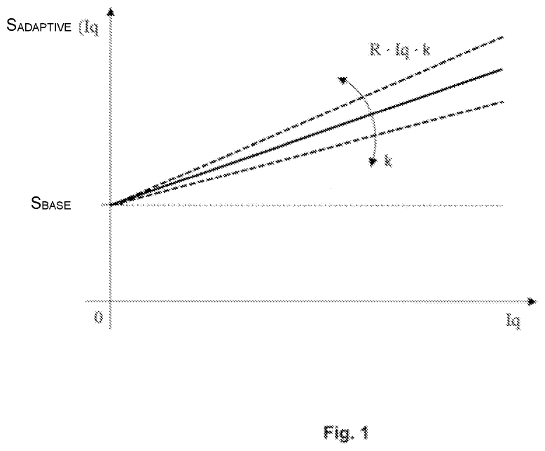

The disclosure is explained in more detail in the following by using a preferred exemplary embodiment with reference to FIG. 1.

FIG. 1 shows a possibility of correcting the error in the model. The concept is based on the idea that an error only occurs if a current is also flowing (Rₛ(T)·I). For this purpose, the threshold for blockage detection is adaptively adjusted in the software and starts with the EMF basic threshold (BEMF threshold). Under laboratory conditions, it is determined at a specific reference temperature of e.g. 20° C. The correction factor k (which corresponds to the gradient of the curve) is used to weigh the correction term for the EMF threshold, depending on which current I_{q} is flowing. This results in an adaptive adjustment of the threshold, starting from which a standstill or a blockage is detected, according to the formula:

Adaptive Threshold=EMF-Base Threshold+Rₛ·I·k

The implementation of the disclosure is not limited to the preferred exemplary embodiments specified above. Rather, a number of variants are conceivable that make use of the solution shown also with fundamentally different designs.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method for detecting a blockage condition of an electric motor, preferably a BLDC motor, that is operated by commutation electronics, wherein the blockage condition is determined by evaluating the EMF in comparison to a stored threshold value S_{BASE} comprising:
a) determining the EMF by taking into account a temperature-dependent parameter representing the stator resistance R of the motor;
b) determining a deviation of the determined EMF due to the influence of the actual winding temperature;
c) determining a correction factor k for correcting the parameter for the stator resistance in order to determine a corrected EMF and
d) determining whether the motor is blocked by comparing the temperature-corrected EMF to the stored threshold value.

2. The method of claim 1, further comprising detecting the temperature of the motor windings for determining a correction factor k by a sensor, preferably a temperature sensor, and adjusting the parameter for the stator resistance R accordingly to determine the EMF.

3. The method of claim 2, further comprising determining the temperature for determining a correction factor k, instead of measuring the temperature of the motor windings, indirectly by a sensor which measures a temperature at another motor reference position or motor module.

4. The method of claim 1, further comprising adaptively adjusting the threshold value S_{ADAPTIVE} for the blockage detection according to the motor current I, in particular via a current-dependent function for the threshold value according to the following formula:
S_{ADAPTIVE}=S_{BASE}+R·I·k,
where S_{BASE} is the stored threshold, R is the stator resistance, I is the motor current and k is a specific correction factor.

5. The method of claim 1, further comprising storing values for the correction factor k.

6. The method of claim 1, further comprising storing switchable values for the correction factor k.

7. The method of claim 1, further comprising storing a term or a corresponding characteristic map for determining the correction factor k.

8. The method of claim 1, wherein, in order to determine the EMF based on the motor voltage, at least the parameters stator resistance R, inductance in the Q-axis L_{q}, inductance in the D-axis L_{d} are taken into account and determined according to the following equations:
$${u}_{d} = R \cdot {i}_{d} - {ω}_{el} \cdot {L}_{q} \cdot {i}_{q} + {L}_{d} \cdot \frac{a}{dt} {i}_{d} \\ {u}_{q} = R \cdot {i}_{q} + {ω}_{el} \cdot {L}_{d} \cdot {i}_{d} + {L}_{q} \cdot \frac{d}{dt} {i}_{q} + {ω}_{el} \cdot {Ψ}_{PM}$$
where the term ωₑₗ·Ψ_{PM} corresponds to the u__{EMF} or the EMF.

9. The method of claim 1, wherein during the evaluation of the EMF, specifically the deviation of the EMF caused by the respective temperature of the motor winding with respect to an EMF at a defined ambient temperature of preferably 20° C. is determined, a parameter corrected by a correction factor k is used for the stator resistance R and the correction factor takes into account the difference between the actual motor winding temperature and a reference temperature.
